(19) United States
(12) Patent Application Publication
(10) Pub. No.: US 2011/0024899 A1
(43) Pub. Date: Feb. 3, 2011

(54) SUBSTRATE STRUCTURE FOR CAVITY PACKAGE

(76) Inventors: Kenji MASUMOTO, Hayami-gun (JP); Masazumi Amagai, Tsukuba-city (JP); Masayuki Yoshino, Oita-city (JP); Yukio Moriyama, Beppu-city (JP)

Correspondence Address: TEXAS INSTRUMENTS INCORPORATED, P O BOX 655474, M/S 3999, DALLAS, TX, 75265, US

(21) Appl. No.: 12/510,781

(22) Filed: Jul. 28, 2009

(51) Int. Cl. H01L 23/498; H01L 21/98

(52) U.S. Cl. 257/737; 438/108; 438/107; 257/E23.07; 257/E21.705

(57) ABSTRACT

Various embodiments provide semiconductor devices having cavity substrate structures for package-on-package assembly and methods for their fabrication. In one embodiment, the cavity substrate structure can include at least one top interconnect via formed within a top substrate. The top substrate can be disposed over a base substrate having at least one base interconnect via that is not aligned with the top interconnect via. Semiconductor dies can be assembled in an open cavity of the top substrate and attached to a base center portion of the base substrate of the cavity substrate structure. A top semiconductor package can be mounted over the top substrate of the cavity substrate structure.

### DESCRIPTION OF THE INVENTION

1. Field of the Invention

The invention relates generally to semiconductor device assembly and packaging and, more specifically, to fabricating integrated circuit (IC) devices having three dimensional packaging.

2. Background of the Invention

It is well known that the consumers of the next generation electronic devices expect those devices to have increased functions and features that are packed in a smaller size, consume less power, and cost less than previous devices. Semiconductor device manufacturers are responding by incorporating improved three dimensional packaging technologies such as package-on-package (PoP), multi-chip packages (MCPs), systems in package (SiP), as well as others. These packing technologies provide vertical stacking of one or more semiconductor dies and/for packages that are integrated to operate as one semiconductor device. For example, PoP packages are commonly used in products desiring efficient access to memory while reducing size, such as cellular telephones.

PoP typically includes at least one die such as a logic chip assembled on a substrate. A top surface of the substrate is used as a receptor to mount a top package such as a memory chip. The top package is electrically coupled to the substrate by ball grid arrays (BGAS) or the like. The substrate for PoP includes a cavity substrate often used for fine pitch memory interface in order to compensate low stand-off height of fine pitch solder balls and to allow solder balls to connect to the memory interface pad. The cavity substrate may be fabricated as a monolith substrate or as multiple substrates attached together to form a center cavity for mounting the logic chip in the bottom package.

### SUMMARY OF THE INVENTION

Conventional cavity substrate structures for semiconductor devices having PoP allow narrow ball pitch solder balls to electrically connect the top package to the bottom package. The inventors have realized, however, that problems arise due to the reliability issues of the cavity substrate structure.

In particular, conventional devices having PoP typically include top solder balls for connecting the top package with a cavity substrate structure that has at least one die mounted in its center cavity. Conventional devices having PoP also include bottom solder balls for connecting the cavity substrate with an external circuit such as a mother board. The top solder balls and the bottom solder balls often have the same or similar pitch value. That is, the center-to-center spacing between adjacent top balls and the center-to-center spacing between adjacent bottom balls are equal or close to each other, wherein each top solder ball is aligned with a corresponding bottom solder ball having a vertical alignment line across the cavity substrate structure. Through this vertical alignment line, an electric feed may be supplied directly from the top solder ball to the corresponding bottom solder ball.

Conventional cavity substrate structures for semiconductor devices having PoP may include laminated substrates having a top substrate and a base substrate. Electrical interconnects such as top interconnects and base interconnects are formed in the top substrate and the base substrate, respectively. The top interconnects and base interconnects are aligned along the vertical alignment line between the top solder ball and the bottom solder ball across the cavity substrate structure.

The inventors have observed crack failures at the interface between the top substrate and the base substrate of conventional cavity substrate structures, for example, during board level temperature cycling tests. This is because thermal stress, such as a sheer stress, can be generated during the temperature cycling, which may further generate tensile force along the alignment line across the cavity substrate structure.

The inventors have realized that new substrate structures for cavity packages (or new cavity substrate structures), new semiconductor devices and their formation methods are therefore needed to overcome these and other problems of the prior art and to improve the reliability of the cavity substrate structure for semiconductor devices having PoP.

To address the crack issues caused by thermal stress along the alignment line of the electrical interconnects, the inventors have discovered a new cavity substrate structure having top interconnect vias in the top substrate (and/or base interconnect vias in the base substrate) displaced or offset from the alignment line between top and bottom conductive bumps (e.g., solder balls) across the inventive cavity substrate structure. This is different from conventional cavity substrates that have each of the top/base interconnect via aligned with the alignment line across the cavity substrate structure.

The disclosed substrate interconnect offset/displacement for semiconductor devices having PoP is desired, because if there is no such offset, when a memory package is mounted on a cavity substrate structure, memory package warpage occurs due to the generated thermal stress applied directly to the substrate interface of the cavity substrate structure since it is in turn mounted and fixed on a mother board Such memory package warpages are often observed in a subsequently development stage.

By offsetting the interconnection vias in the cavity substrate structure from the alignment line across the cavity substrate structure, thermal stress generated from temperature cycling stage of device fabrication can be reduced or eliminated, as analyzed by BLR modeling. Shear stress generated at substrate interface can then be measured. In one exemplary modeling simulation for a semiconductor device with a pitch of about 0.5 mm for top/bottom conductive bumps (e.g., solder balls), sheer stress can be significantly reduced by about 34% for an offset distance of about 0.25 mm.

The term “offset distance” refers to a distance of a top interconnect via in the top substrate of the disclosed cavity substrate structure (or a base interconnect via in the base substrate) displaced from a corresponding vertical alignment line between a top conductive bump and a bottom conductive bump across the cavity substrate structure. The “offset distance” can be a center-to-center distance between the alignment line and the top interconnect via (or the base interconnect via). In various embodiments, the offset distance can be at least about 20 microns. In various other embodiments, the offset distance can be less than a half of a pitch of the plurality of top/bottom conductive pumps.

In addition, more heat cycles can be performed on the inventive semiconductor device having PoP. For example, the inventive semiconductor device having PoP can pass 1000 temperature cycles in a standard temperature cycling test, on the contrary, conventional devices can run about 76 temperature cycles in one example.

Further, the semiconductor device having the improved cavity substrate structure can be advantageously manufactured by using existing laminate substrate materials and processes, and using existing interconnection materials and processes such as solder on pad. Use of existing materials and processes can advantageously enable multiple substrate contractors to perform the manufacturing.

The technical advances represented by the present teachings, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIGS. 1A-1E depict a semiconductor device having PoP at various fabrication stages in accordance with various embodiments of the present teachings;

FIG. 2 depicts an exemplary method for forming the semiconductor device having PoP in accordance with various embodiments of the present teachings;

FIG. 3 depicts shear stress results for an exemplary semiconductor device having PoP in accordance with various embodiments of the present teachings; and

FIG. 4 depicts a second exemplary semiconductor device having PoP in accordance with various embodiments of the present teachings;

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to exemplary embodiments of the invention, examples of which are illustrated in the accompanying drawings. Wherever possible, the same reference numbers will be used throughout the drawings to refer to the same or like parts.

In semiconductor device manufacturing, a substrate structure can be used as an underlying material, for example, for assembling or fabricating a semiconductor die In addition to providing a mechanical substrate/support for a semiconductor device and its formation, the substrate structure can also be used to provide electrical interconnections between components of semiconductor devices, such as between a semiconductor die and external circuits.

As used herein, the term “substrate structure for cavity package” or “cavity substrate structure” refers to a substrate structure that includes a top substrate having an open cavity disposed over a base substrate. Specifically, the base substrate can be formed to include a base center portion and a peripheral portion having a plurality of base interconnect vias formed in the peripheral portion. The top substrate can be disposed over the peripheral portion of the base substrate and can have the open cavity, an open top center portion, matching the base center portion of the base substrate. In one embodiment, at least one semiconductor die can be attached to the base center portion in the open cavity using die and wire bonding or flip-chip interconnection The top substrate can further include a plurality of top interconnect vias, such as top through-hole interconnect vias.

A plurality of top conductive bumps, such as top solder balls, can be disposed over the top substrate for connecting the cavity substrate structure with a top package for the PoP.

A plurality of bottom conductive bumps, such as bottom solder balls, can be attached to the base substrate on the backside for connecting the cavity substrate structure with external circuits such as a mother board.

Each top conductive bump (or top solder ball) can be aligned with a corresponding bottom conductive bump (or bottom solder ball) to form an alignment line across the cavity substrate structure that includes the top substrate laminated over the base substrate

Corresponding top conductive bumps, top interconnect vias, base interconnect vias, and bottom conductive bumps can be electrically interconnected. Unlike the conventional cavity substrate structure, one of the top interconnect vias and the base interconnect vias can be formed offsetting from the alignment line between the top and bottom conductive bumps across the cavity substrate structure.

In various embodiments, the top substrate and/or the bottom substrate for the disclosed cavity substrate structure can include a stack of thin layers or laminates, and can often be referred to as a “laminate substrate”.

The “laminate substrate” can usually be made of, for example, polymer-based material such as epoxy-based laminate FR-4, FR-5 or their equivalents, or fiber-reinforced material such as BT (bismaleimide triazine) resin. Other types of laminate substrates can include an organic substrate and/or a ceramic substrate. The laminate substrate can typically include multiple conductive layers, e.g., a 1/2/1 4-metal-layer substrate as known to one of ordinary skill in the art. In some applications, the laminate substrate can include a single layer of dielectric and a single layer of metal. Interconnect vias such as through-hole plated vias can provide electrical coupling between these multiple layers. The conductive layers typically include traces of a metal foil bonded to a polymer substrate.

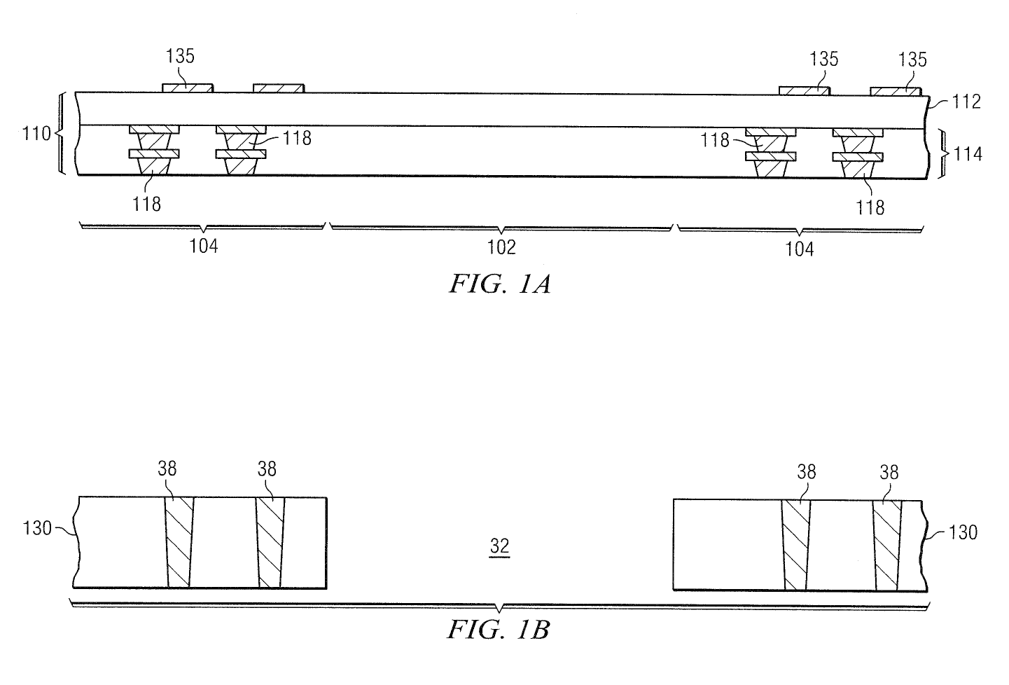

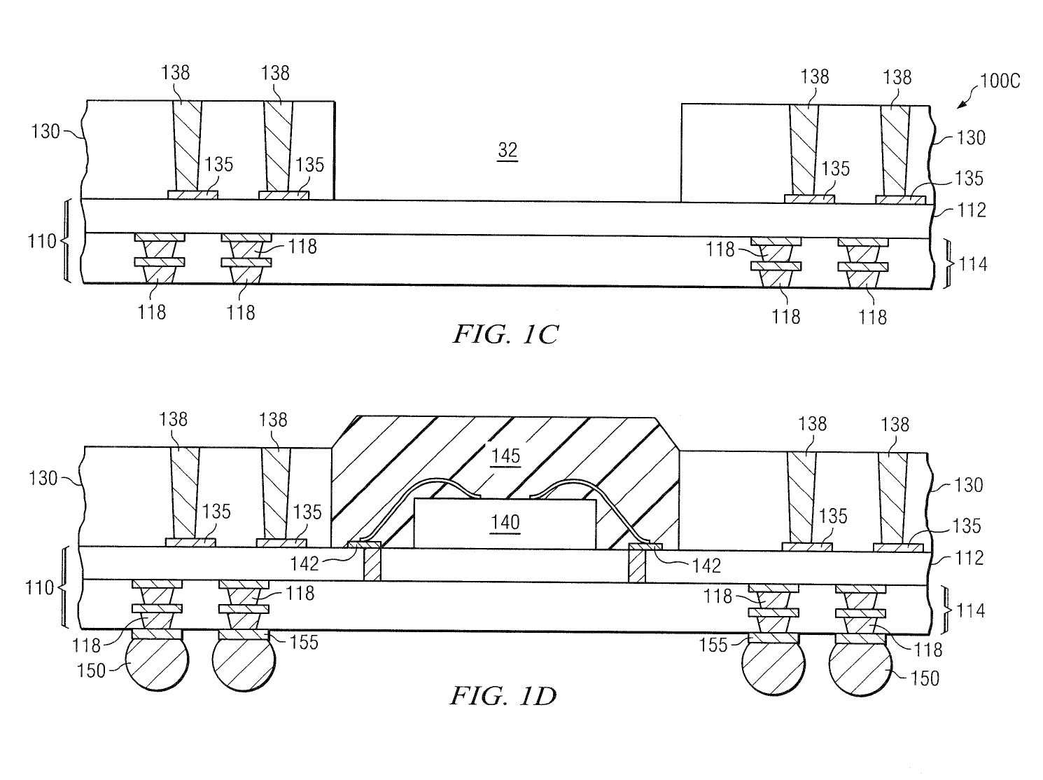

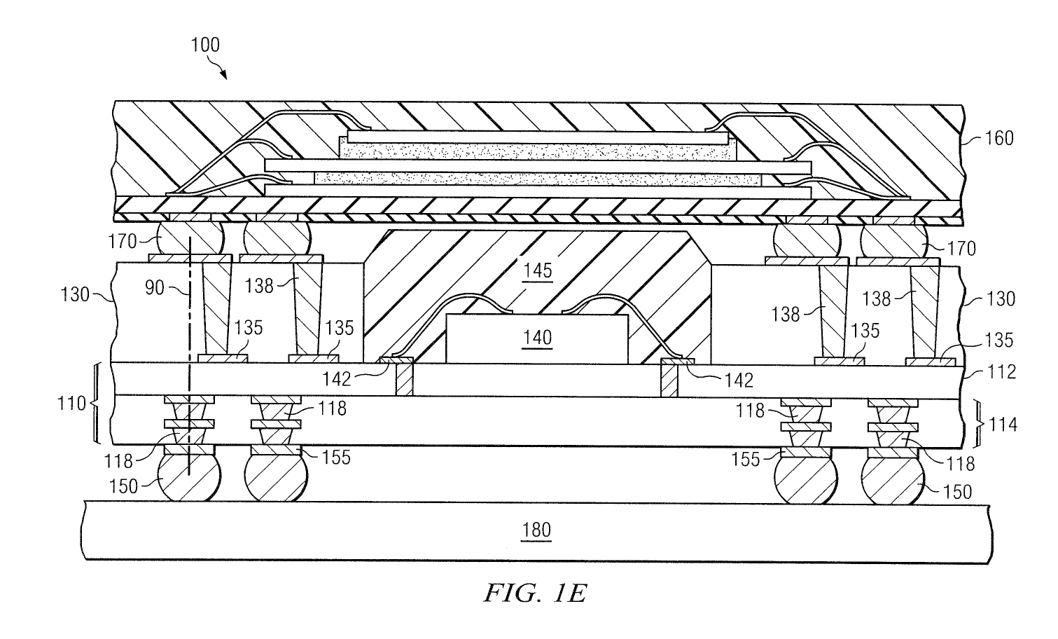

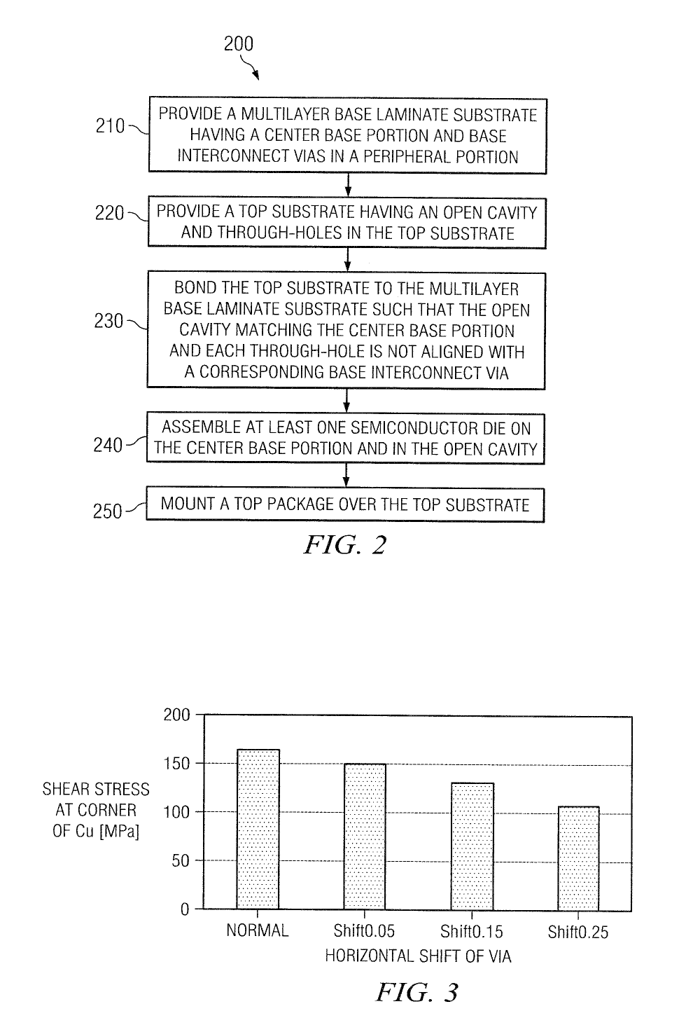

FIGS. 1A, 1B, 1C, 1D, 1E and FIG. 2 describe the fabrication of a semiconductor device having a PoP structure in accordance with various embodiments of the present teachings.

FIGS. 1A-1E illustrate a simplified and schematic cross section of an exemplary cavity substrate structure of an exemplary semiconductor device 100 having a package-on-package (PoP) at various fabrication stages in accordance with various embodiments of the present teachings. It should be readily apparent to one of ordinary skill in the art that the device depicted in FIGS. 1A-1E represents a generalized schematic illustration and that other components/devices can be added or existing components/devices can be removed or modified.

In FIG. 1A, an exemplary multilayer base substrate 110 for the cavity substrate structure of the semiconductor device 100 can be formed or-provided to include a core layer 112 and other laminated layers 114. The multilayer base substrate 110 can be a laminate substrate made by organic laminate substrate technology as known to one of ordinary skill in the art. In a particular embodiment, the base laminate substrate 110 can be fabricated using a process flow involving incoming material, drill-desmear, plating, dry film resist (DF) laminate-exposure-development, plating, strip and etch, outer layer lamination, drill, plating, imaging, strip and etch.

For example, the core layer 112 can be made of conventional materials, such as epoxy and fiberglass, and may have a glass transition temperature (Tg) associated with it that varies, depending on the material from which the core layer 112 is made.

The base laminate substrate 110 can also include a base center portion 102 and a peripheral portion 104 surrounding the base center portion 102. The base center portion 102 can be suitable for mounting at least one semiconductor die there-over. The multilayer base substrate 110, in particular, the laminated layers 114 can further include base interconnect vias 118 for electrical interconnections, e.g., between the at least one die and external circuits.

As shown in FIG. 1A, a plurality of contact pads 135 can also be formed and positioned on front side surfaces of the peripheral portion 104 of the base laminate substrate 110 for receiving and electrically connecting a top package as shown in FIG. 1B. Each contact pad 135 can be associated with, or electrically connected with, the base interconnect vias 118 and may or may not be offset from the base interconnect vias 118.

In FIG. 1B, a top substrate 130 for the cavity substrate structure can be formed separately. In one embodiment, the top substrate 130 can be a picture-frame shaped top laminate substrate. The top substrate 130 can have an open portion, an open cavity 32, associated with the base center portion 102 for a subsequent lamination of the cavity substrate structure. The top substrate 130 can also include deep through-holes 38.

In FIG. 1C, a cavity substrate structure 100C can be formed by laminating the formed top substrate 130 over the multilayer base substrate 110 having the open top center cavity 32 match the underlying base center portion 102. As shown, the top substrate 130 can be attached to the peripheral portion 104 of the base laminate substrate 110. Specifically, the exemplary frame shaped top substrate 130 can be laminated on the core layer 112 of the multi-layer base substrate 110.

When attaching or laminating the top substrate 130 to the multilayer base substrate 110, deep through-holes 38 (see FIG. 1B) of the top substrate 130 can contact, or in some cases, be aligned with the contact pads 135 on the base substrate 110, but offset from the base interconnect vias 118 in the base substrate 110. In various embodiments, adhesive coupling or other suitable techniques can be used for attaching the top substrate 130 to the multilayer base substrate 110.

Following the lamination, the deep through-holes 38 can be filled with metal or metal alloys to form top interconnect vias 138. For example, the top interconnect vias 138 can include metal or metal alloys that are made by an electro-deposition process, an electroless deposition process, a wave soldering, a stencil printing or combinations thereof. The metals or metal alloys used herein can include, for example, Pb, Sn, In, Ag, Au, Cu, Ni or combinations thereof. In various embodiments, other suitable conductive materials known to one of ordinary skill in the art can also be used including, for example, a solder paste, or a conductive polymer material such as metal filled epoxy processed by a stencil printing technique. In an exemplary embodiment, the top interconnect via 138 can be formed by a copper plating on a wall of the deep through-holes 38, followed by filling a conductive paste into the plated through-hole.

In various embodiments, the cavity substrate structure 100C can have a thickness of about 100 to about 200 micrometers, although thinner or thicker substrates may be possible depending on a number of layers included in the top and base substrate 130/110

In various embodiments, the top substrate 130 can be a laminate substrate that is essentially the same or different from the base substrate 110. In an exemplary embodiment, the base laminate substrate 110 can be a 2 or more metal layer substrate, e.g., a 1/2/1 substrate, and the top substrate 130 can be at least one metal layer substrate.

In FIG. 1D, at least one semiconductor die 140 can be assembled in the open cavity 32 and attached to the base center portion 102 of the base substrate 110 by, for example, a die attach compound (not shown). In various embodiments, more dies, such as a second die (not shown) can be attached to the die 140. Although the die 140 is shown to be connected to the base center portion 102 as wire bond connections, one of ordinary skill in the art would understand that different connection techniques, such as flip chip may be used to electrically couple the die to its contact pads 142.

The open cavity 32 assembled with the at least one die can then be filled with a molding compound 145, such as a polymeric molding compound, to protect and hold the die 140 in place. In various embodiments, the at least one die included in the semiconductor device 100 can be one of a microprocessor, a digital signal processor, a radio frequency chip, a memory, a microcontroller, an application specific integrated circuit, and a system-on-a-chip or a combination thereof. In an embodiment, the thickness of the top substrate 130 can be adjustable in dependence of the connection technique used, such as flip chip or wire bond or the number of the dies assembled.

Opposing the die side, on the backside of the base substrate 110, conductive bumps such as bottom solder balls 150 can be attached to the base substrate 110 connecting the base interconnect vias 118 through contact pads 155. In one embodiment, the solder ball conductive bumps 150 can be formed by applying a reflowable solder in a paste, powder, or film form to the contact pad 155 on the base substrate 110. Other materials used for forming the conductive bump can include anisotropic conductive paste. Metals such as copper, gold metals or alloys thereof may also be used to form the conductive bumps. In one embodiment, the shape of the conductive bump can be in the form of a convex surface.

FIG. 1E illustrates a simplified and schematic cross section of a semiconductor device 100 having a package-on-package structure described with reference to FIGS. 1A, 1B, 1C and 1D, according to various embodiments of the present teachings. For example, a top package 160 such as a memory chip can be mounted on the top substrate 130 to form package-on-package (PoP) structure of the semiconductor device 100. The top package 160 can be coupled to the top laminate substrate 130 through conductive bumps, such as top solder balls 170 in a ball-grid array (BGA) or other conductive bumps as disclosed herein. In various embodiments, the top conductive bump solder balls 170 can be the same or different from the bottom conductive bump solder balls 150 having a similar pitch of about 0.4 mm or greater, such as, from about 0.4 mm to about 0.65 mm for the top and bottom conductive bumps of the cavity substrate structure.

Mother board 180 such as a printed circuit board can be attached to the base substrate 110 through the bottom solder balls 150 from the backside of the base substrate 110.

FIG. 2 is a flow chart illustrating a method for fabricating a semiconductor device having a package-on-package structure, according to various embodiments of present teachings. In a particular embodiment, FIG. 2 illustrates the process for fabricating the semiconductor device 100 described with reference to FIGS. 1A, 1B, 1C, 1D and 1E.

While the method 200 of FIG. 2 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein Also, not all illustrated steps may be required to implement a methodology in accordance with one or more aspects or embodiments of the present invention. Further, one or more of the acts depicted herein may be carried out in one or more separate acts and/or phases.

At 210, a multilayer base laminate substrate can be formed or provided to include base interconnect vias through one or more layers of the multilayer base laminate substrate. The base laminate substrate can include a base center portion and a peripheral portion surrounding the base center portion. The base center portion can be capable of mounting at least one die. The peripheral portion can includes a plurality of contact pads for receiving a top package. Each contact pad can be associated with one base interconnect via and may or may not be offset from the base interconnect via.

At 220, a top substrate can be formed or provided separately from the multilayer base laminate substrate. The top substrate can include an open center cavity and a plurality of through-holes in the non-open portion.

At 230, the top substrate can be attached to the multilayer base laminate substrate such that the through-holes of the top substrate can be offset from the base interconnect vias of the base substrate, and the open cavity of the top substrate can match the base center portion of the base laminate substrate. The through-holes of the top substrate can then be metal plated to form electrical interconnections connecting with the contact pads formed on the base substrate.

At 240, at least one die can be mounted on the base center portion using a flip chip type or a wirebond type interconnection. The open cavity can then be filled by a molding compound to encapsulate the at least one die. Additionally, bottom conductive bumps, such as solder balls, can be formed on the backside, opposing the die side, of the base substrate connecting the base interconnect vias.

At 250, a top package can be mounted on the top substrate through top conductive bumps such as top solder balls to form the package-on-package structure of the semiconductor device 100. To complete the assembly of the semiconductor device, a mother board such as printed circuit board can be attached to the cavity structure from the backside of the base laminate substrate through the bottom conductive bumps.

Several advantages are achieved by the methods, structures and devices described herein. As shown in FIG. 1E, the embodiments advantageously provide an improved cavity substrate structure for PoP assembly by offsetting the top interconnect vias 138 from an alignment line 90 between the top and bottom solder ball conductive bumps across the cavity substrate structure that includes the top substrate and the multilayer base substrate In various embodiments, the base interconnect vias 118 may or may not offset from the alignment line 90.

This inventive cavity substrate structure is different from conventional cavity substrate structure that has top solder balls (for receiving a top package), top interconnect vias, base interconnect vias, and bottom solder balls (for connecting a mother board) aligned together along the alignment line. By offsetting the top interconnect vias 138, crack issues can be avoided or eliminated

FIG. 3 depicts exemplary results of shear stress generated at corners of interconnect vias having various offset distances. As shown, when the offset distance increases, the shear stress can be significantly reduced.

Additionally, the semiconductor device having the improved cavity substrate structure can be advantageously manufactured by using existing laminate substrate materials and processes, and using existing interconnection materials and processes such as solder on pad. Use of existing materials and processes advantageously enables multiple substrate contractors to perform the manufacturing.

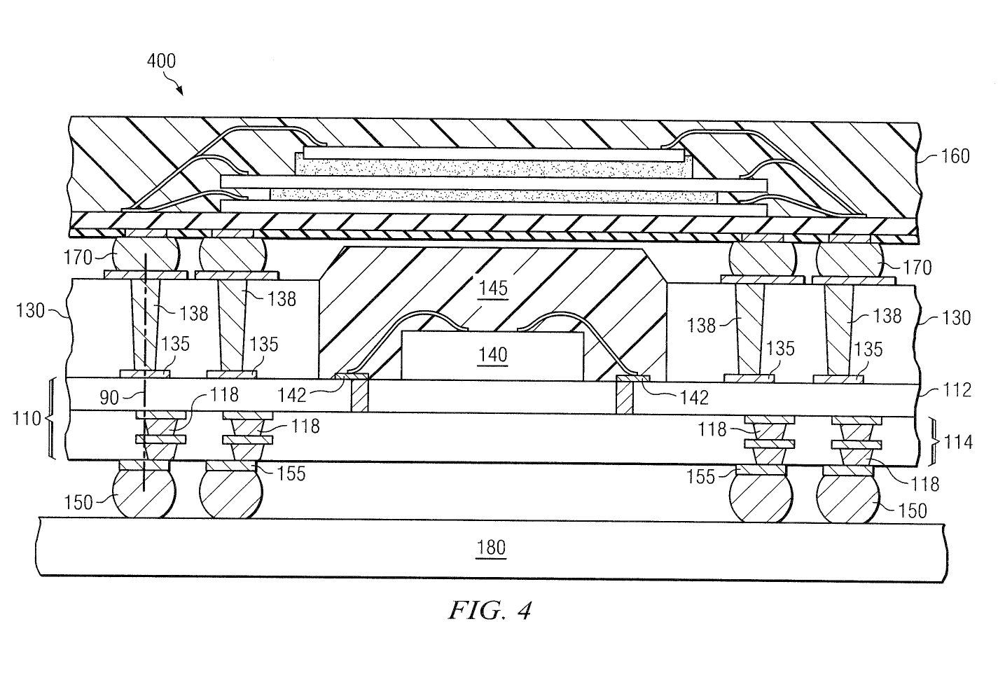

In various embodiments, the inventive cavity substrate structure can alternatively include the base interconnect vias 118 formed offsetting from the alignment line 90 of the conductive bumps 150/170 across the cavity substrate structure, as illustrated in FIG. 4. Crack issues due to the alignment shown in conventional substrate structures can then be avoided or eliminated.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising”. Further, in the discussion and claims herein, the term “about” indicates that the value listed may be somewhat altered, as long as the alteration does not result in nonconformance of the process or structure to the illustrated embodiment. Finally, “exemplary” indicates the description is used as an example, rather than implying that it is an ideal.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device comprising:
a multilayer base substrate comprising a base center portion surrounded by a peripheral portion, wherein a base interconnect via is disposed in the peripheral portion;
a top substrate disposed over the multilayer base substrate having an open cavity matching the base center portion, wherein a through-hole interconnect via is disposed through the top substrate;
a top conductive bump disposed over the top substrate for receiving a semiconductor package; and
a bottom conductive bump attached to the multilayer base substrate and aligned with the top conductive bump along an alignment line;
wherein the top conductive bump, the through-hole interconnect via, the base interconnect via, and the bottom conductive bump are electrically interconnected; and either the through-hole interconnect via or the base interconnect via is disposed offset from the alignment line between the top and bottom conductive bumps.

2. The device of claim 1, further comprising at least one semiconductor die attached to the base center portion in the open cavity; and a molding compound to encapsulate the at least one semiconductor die and to fill the open cavity.

3. The device of claim 2, wherein the at least one semiconductor die is a flip chip die or a wire-bonded die.

4. The device of claim 2, wherein the at least one semiconductor die is one of a microprocessor, a digital signal processor, a radio frequency chip, a memory, a microcontroller, a system-on-a-chip or a combination thereof.

5. The device of claim 1, wherein the one of the through-hole interconnect via and the base interconnect via is offset at least about 20 microns from the alignment line.

6. The device of claim 1, further comprising a plurality of top conductive bumps, a plurality of through-hole interconnect vias, a plurality of base interconnect vias, and a plurality of bottom conductive bumps with each corresponding top conductive bump, through-hole interconnect via, base interconnect via, and bottom conductive bump electrically interconnected.

7. The device of claim 6, wherein the plurality of top conductive bumps or the plurality of bottom conductive bumps has a pitch ranging from about 0.4 mm to about 0.65 mm.

8. The device of claim 7, wherein the one of the through-hole interconnect via and the base interconnect via is offset from the alignment line for less than a half of the pitch of the plurality of top conductive pumps

9. The device of claim 1, wherein the top substrate includes at least one metal layer.

10. The device of claim 1, wherein each of the top and bottom conductive bumps comprises a solder ball.

11. The device of claim 1, wherein the multilayer base substrate is an organic substrate, a ceramic substrate, a glass epoxy substrate, or a bismaleimide triazine (BT) substrate.

12. A method for forming a semiconductor device comprising:
providing a multilayer base laminate substrate comprising a base center portion surrounded by a peripheral portion that includes a plurality of base interconnect vias, wherein the base center portion is capable of mounting at least one die;
providing a top substrate comprising an open cavity and a plurality of through-holes in the top substrate;
bonding the top substrate to the multilayer base laminate substrate such that the open cavity matches the base center portion, and each through-hole of the top substrate is not aligned with a corresponding base interconnect via of the multilayer base laminate substrate;
filling each through-hole of the top substrate with a metal to form a plurality of top interconnect vias;
assembling at least one die on the base center portion in the open cavity; and
mounting a top package on the top substrate through a plurality of top conductive bumps to form a package-on-package structure.

13. The method of claim 12, further comprising an adhesive coupling for bonding the top substrate and the multilayer base laminate substrate.

14. The method of claim 12, further comprising forming a plurality of contact pads on the multilayer base laminate substrate, wherein each contact pad connects to a corresponding through-hole in the top substrate during the bonding.

15. The method of claim 12, wherein the formation of the plurality of top interconnect vias further comprises plating a wall of each through-hole in the top substrate with a copper and filling the plated through-hole with a metal paste.

16. The method of claim 12, wherein the metal used to form the plurality of top interconnect vias comprises Pb, Sn, In, Ag, Au, Cu, Ni or a combination thereof.

17. The method of claim 12, wherein the assembly of at least one die on the base center portion comprises one of a flip chip type and a wire bond type interconnection.

18. The method of claim 12, further comprising filling the open cavity by a molding compound to encapsulate the assembled at least one die.

19. The method of claim 12, further comprising attaching a printed circuit board to the multilayer base laminate substrate through a plurality of bottom conductive bumps each aligned with a corresponding top conductive bump.

20. A semiconductor device comprising:
a cavity substrate structure comprising a bottom solder ball attached on a backside, and a top solder ball attached on a front side and aligned with the bottom solder ball to form an alignment line; wherein the cavity substrate structure comprises:
a multilayer base laminate substrate having a base center portion surrounded by a peripheral portion that further comprises a base interconnect via,
a top substrate disposed over the multilayer base laminate substrate having an open cavity matching the base center portion, wherein the top substrate comprises a through-hole interconnect via, and wherein the top solder ball, the through-hole interconnect via, the base interconnect via, and the bottom solder ball are electrically interconnected; and one of the through-hole interconnect via and the base interconnect via is offset from the alignment line;
at least one semiconductor die attached on the base center portion in the open cavity of the cavity substrate structure; and
a top package disposed over the cavity substrate structure by the top solder ball.
